(19) United States
(12) Patent Application Publication
(10) Pub. No.: US 2017/0160569 A1
(43) Pub. Date: Jun. 8, 2017

(54) ARRAY SUBSTRATE HAVING CONDUCTIVE PLANAR LAYER AND METHOD OF MANUFACTURING THE SAME

(71) Applicant: BOE TECHNOLOGY GROUP CO., LTD., Beijing (CN)

(72) Inventor: Ze Liu, Beijing (CN)

(21) Appl. No.: 15/117,556

(22) PCT Filed: Dec. 11, 2015
(86) PCT No.: PCT/CN2015/097124

§ 371 Date: Aug. 9, 2016

(30) Foreign Application Priority Data
Jul. 29, 2015 (CN) 201510453722.7

(51) Int. Cl. G02F 1/061; B82B 3/00; H01L 51/56; G09G 3/34; H01L 51/52

(52) U.S. Cl. CPC G02F 1/061; G09G 3/3426; H01L 51/52; H01L 51/56; B82B 3/0009

(57) ABSTRACT

An array substrate includes a substrate (100) having a plurality of sub-pixel regions. Each sub-pixel region includes: a switching element (1) disposed on the substrate, a conductive planar layer (113) disposed on the switching element (1), and a pixel electrode (111) disposed on the conductive planar layer (113), the pixel electrode (111) being electrically connected to the output electrode (105) of the switching element (1). Such array substrate improves the instability of the device caused by stress between materials, enhances the long-term stability of the device, and simplifies the manufacturing process.

### TECHNICAL FIELD

Embodiments of the present invention relate to an array substrate having a conductive planar layer, a display device including the same, and a method of manufacturing the same.

### BACKGROUND

In an organic electroluminescent display device, the reflective anode on an array substrate is typically prepared using an ITO/Ag or AlNd/ITO structure, wherein Ag or AlNd is used as a reflective electrode and ITO is used as a transparent conductive anode. In the production of the array substrate, the switching element such as a thin film transistor (TFT) on the array substrate will generate some steps. Thus, an organic resin planar layer is generally deposited on the switching element, and then the ITO/Ag or AlNd/ITO electrode is deposited on the organic resin planar layer. However, due to the stress mismatch between the organic resin material and the electrode material, the organic resin planar layer electrode may easily fall off, and the passing rate and long-term stability of the device are problematic.

Therefore, there is a need in the art for an improved array substrate structure to improve the passing rate and long-term stability of the device.

### SUMMARY OF THE INVENTION

Embodiments of the present invention relate to an array substrate, a display apparatus comprising the same, and a method of manufacturing the same. The present invention includes the following content:

Embodiment 1. An array substrate, comprising: a substrate having a plurality of sub-pixel regions, wherein the array substrate in each sub-pixel region comprises: a switching element disposed on the substrate, a conductive planar layer disposed on the switching element, and a pixel electrode disposed on the conductive planar layer, the pixel electrode being electrically connected to an output electrode of the switching element. Such array substrate improves the device instability caused by stress between materials, enhances the long-term stability of the device, and simplifies the production process because the planar layer and the pixel electrode are both comprised of inorganic materials.

Embodiment 2. The array substrate according to Embodiment 1, wherein the conductive planar layer is a metal-containing conductive planar layer.

Embodiment 3. The array substrate according to Embodiment 1 or 2, wherein the conductive planar layer is formed by sintering a nanoscale metal material.

Embodiment 4. The array substrate according to Embodiment 3, wherein the nanoscale metal material is a metal nano-wire, a metal nano-particle, or a combination thereof.

Embodiment 5. The array substrate according to any one of Embodiments 1 to 4, further comprising a pixel isolation layer which separates and insulates the conductive planar layers in different sub-pixel regions from each other.

Embodiment 6. The array substrate according to any one of Embodiments 1 to 5, wherein the conductive planar layer has a thickness of equal to or greater than 10 nm to less than 1 μm.

Embodiment 7. The array substrate according to any one of Embodiments 1 to 6, wherein the pixel electrode is electrically connected to the output electrode of the switching element via the conductive planar layer.

Embodiment 8. The array substrate according to any one of Embodiments 1 to 7, wherein an inorganic buffer layer is disposed between the switching element and the conductive planar layer.

Embodiment 9. The array substrate according to Embodiment 4, wherein the nanoscale metal material comprises a nanoscale silver material.

Embodiment 10. The array substrate according to Embodiment 8 or 9, wherein the inorganic buffer layer has a thickness of from 50 nm to 1500 nm.

Embodiment 11. The array substrate according to any one of the Embodiments 1 to 10, wherein the switching element is a thin film transistor and the output electrode of the switching element is a drain electrode of the thin film transistor.

Embodiment 12. The array substrate according to any one of Embodiments 1 to 11, wherein the array substrate further comprises an organic light-emitting layer above the pixel electrode and a transparent electrode above the organic light-emitting layer.

Embodiment 13. The array substrate according to any one of Embodiments 1 to 12, wherein the conductive planar layer and the pixel electrode are in direct contact with each other.

Embodiment 14. The array substrate according to any one of Embodiments 1 to 13, wherein the material of the pixel electrode comprises at least one of transparent conductive oxides such as ITO (indium tin oxide) and IZO (indium zinc oxide), carbon nanotubes and carbon nanowires.

Embodiment 15. A display device comprising the array substrate according to any one of Embodiments 1 to 14.

Embodiment 16. A method of manufacturing an array substrate comprising a substrate having a plurality of sub-pixel regions, wherein the array substrate in each sub-pixel region comprises: a switching element disposed on the substrate, a conductive planar layer disposed on the switching element, and a pixel electrode disposed on the planar layer, wherein the pixel electrode is electrically connected to an output electrode of the switching element, wherein said method comprises the steps of: forming a switching element on each sub-pixel region of the substrate, forming a conductive planar layer on the switching element, and forming a pixel electrode on the conductive planar layer.

Embodiment 17. The method according to Embodiment 16, wherein forming the conductive planar layer on the switching element comprises: applying a nanoscale metal material onto the switching element, and then sintering the nanoscale metal material to obtain the conductive planar layer.

Embodiment 18. The method according to Embodiment 16 or 17, which, prior to forming the conductive planar layer, further comprises forming an inorganic buffer layer on the switching element and etching the inorganic buffer layer to expose the output electrode of the switching element.

Embodiment 19. The method according to any one of Embodiments 16 to 18, which, prior to forming the conductive planar layer, further comprises forming a pixel isolation layer that separates the conductive planar layers in different sub-pixel regions from each other.

Embodiment 20. The method according to Embodiment 19, wherein the pixel isolation layer also separates the pixel electrodes in different sub-pixel regions from each other.

Embodiment 21. The method according to Embodiment 17, wherein the nanoscale metal material is applied by ink-jet printing, screen printing, or transfer printing, and the sintering is performed at a temperature of from 120 to 600° C., for example, at a temperature of from 130 to 560° C.

Embodiment 22. The method according to Embodiment 17, wherein the nanoscale metal material comprises a nanoscale silver material.

### BRIEF DESCRIPTION OF THE DRAWINGS

In order to clearly illustrate the technical solutions of the embodiments of the present invention, the drawings of the embodiments are briefly described below. Apparently, the drawings described below relate to only some embodiments of the present invention and thus are not limitative of the present invention.

FIG. 1 is a schematic view of an array substrate of a top emission type.

FIG. 2 is a schematic view of an array substrate according to an embodiment of the present invention.

FIG. 3 is a schematic view of an array substrate according to an embodiment of the present invention.

FIGS. 4-10 are schematic views illustrating a method of manufacturing an array substrate according to embodiments of the present invention.

### DETAILED DESCRIPTION

To make clearer the objects, technical solutions and advantages of the embodiments of the present invention, a clear and full description of the technical solutions of the embodiments of the present invention will be made with reference to the accompanying drawings of the embodiments of the present invention. Apparently, the described embodiments are just part rather than all of the embodiments of the present invention. Based on the embodiments of the present invention described, all the other embodiments obtained by a person of ordinary skill in the art, without any creative labor, fall within the scope of protection of the present invention.

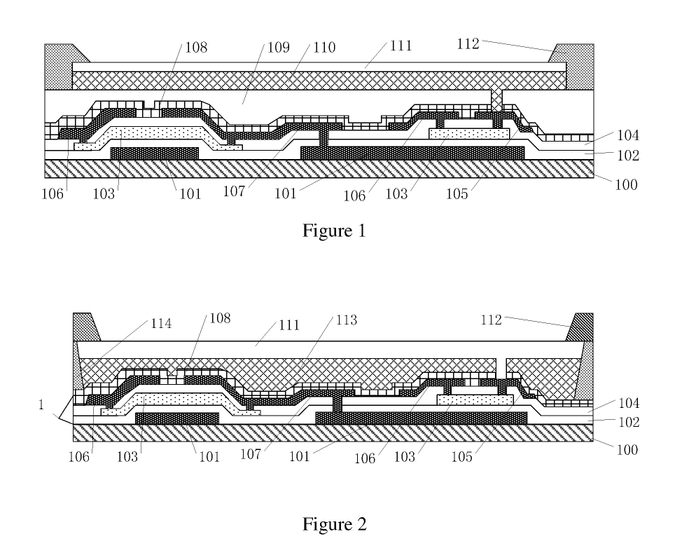

FIG. 1 is a view of an array substrate of a top emission type, comprising: a substrate 100, a gate electrode 101 on the substrate, a gate insulation layer 102, a semiconductor layer 103, an etching barrier layer 104, a source electrode 106, a drain electrode 105, an intermediate metal layer 107, an inorganic insulating layer 108 (optional), an organic resin planar layer 109, a reflective electrode 110, a transparent pixel electrode 111, and a pixel defining layer 112.

The terms in the present application have the meanings generally understood by a person skilled in the art.

For example, the term “switching element” has the meaning generally understood by a person skilled in the art. Generally speaking, in an electronic device, the switching element may be a transistor, in particular a thin film transistor. For example, as indicated by the reference sign “1” in FIG. 2, the switching element 1 may include a gate electrode 101 on the substrate, a gate insulation layer 102, a semiconductor layer 103, an etching barrier layer 104, a source electrode 106, a drain electrode 105 and an intermediate metal layer 107. The structure of the switching element described herein is merely an exemplary structure, and is not limited thereto according to embodiments of the present invention.

Embodiments of the present invention provide an improved array substrate, a display apparatus comprising the same, and a method of manufacturing the same. On the switching element of the array substrate, a nanoscale metal material, in particular a nanoscale silver material, is applied by a process such as ink-jet printing, and is then sintered to a conductive planar layer (the conductive planar layer may also be used as a reflective electrode), followed by depositing ITO as a top emission pixel electrode. Such array substrate improves the device instability caused by stress between materials, enhances the long-term stability of the device, and simplifies the production process because the planar layer and the pixel electrode are both comprised of inorganic materials. In the present application, the term “long-term stability” refers to the reliability and stability of the device during manufacture and use of the device. By using a conductive planar layer in the manufacture of a non-flexible device, the device will not tend to peel, thereby improving the yield. Flexible devices are often deformed and bent, and by using a conductive planar layer, the device will not tend to peel and shed. Therefore, such long-term stability plays an important part in the process of manufacturing and using a flexible device.

Some embodiments of the present invention provide an array substrate comprising a substrate having a plurality of sub-pixel regions, wherein the array substrate in each sub-pixel region comprises: a switching element disposed on the substrate, a conductive planar layer disposed on the switching element, and a pixel electrode disposed on the planar layer, wherein the pixel electrode is electrically connected to the switching element. In one embodiment, the pixel electrode is electrically connected to the output electrode of the switching element. In one embodiment, the switching element is a thin film transistor and the output electrode is a drain electrode of the thin film transistor.

Array substrate is one of the main elements in a display apparatus. Generally speaking, an array substrate includes a plurality of sub-pixel regions, each sub-pixel region forming a sub-pixel, each sub-pixel being capable of emitting light of one color. The luminescent color of each sub-pixel is based on the design. Typically, the three sub-pixels which respectively emit red light, green light and blue light on the array substrate can be used to constitute a pixel. In some embodiments, the four sub-pixels which respectively emit white light, red light, green light and blue light can be used to constitute a pixel.

Generally speaking, the sub-pixel formed in each sub-pixel region at least includes a switching element, a pair of electrodes and an electroluminescent material, the output electrode of the switching element being electrically connected to one electrode of the pair of electrodes and the electroluminescent material being located between the pair of electrodes. Said pair of electrodes generally comprises a pixel electrode, and a common electrode opposite to the pixel electrode. In some embodiments, the pixel electrode is an anode and the common electrode is a cathode.

In one embodiment, the switching element is a transistor, e.g., a thin film transistor. The thin film transistor may be a structure of a top gate type or bottom gate type. There is no limitation to the structure of the thin film transistor of the array substrate suitable for the present invention, which can be a structure generally known to a person skilled in the art.

In one embodiment of the present invention, the array substrate includes a conductive planar layer disposed on the switching element. In the present application, the conductive planar layer has two primary surfaces with one being close to the switching element and the other being close to the pixel electrode, wherein the primary surface close to the switching element is non-planar and the primary surface close to the pixel electrode is planar. In some embodiments, the planar primary surface of the conductive planar layer is parallel to the surface of the substrate. The conductive planar layer is mainly comprised of a metal, and can further serve as a reflective substrate in addition to its function of planarization (for example, planarizing the steps formed by the switching element and the like on the array substrate). A pixel electrode, for example, a transparent top emission anode can be formed on the conductive planar layer. In some embodiments, the conductive planar layer is electrically connected to the pixel electrode and is electrically connected to the output electrode of the switching element. In some embodiments, the pixel electrode is electrically and directly connected to the output electrode of the switching element. In some embodiments, the pixel electrode is formed directly on the conductive planar layer. For example, the pixel electrode may be in direct contact with the conductive planar layer.

In some embodiments, the conductive planar layer is a conductive planar layer comprising a metal. Metal is a good conductor of electricity, and therefore the conductive planar layer of the embodiments of the present invention may contain a metal. In some embodiments, the conductive planar layer is formed by a metal. Compared with the stress difference between the organic planar layer and the reflective electrode on the organic planar layer and between the organic planar layer and the inorganic buffer layer below the organic planar layer, the stress difference between the conductive planar layer formed by a metal and the pixel electrode (for example, ITO) formed on the conductive planar layer and between the conductive planar layer formed by a metal and the inorganic buffer layer formed below the conductive planar layer is smaller, thus improving the instability of the device caused by the stress difference between materials. Because the conductive planar layer can also be used as a reflective electrode, the step of forming a reflective electrode and a planar electrode is integrated into a process step of forming a conductive planar layer, which consequently simplifies the production process of the array substrate according to embodiments of the present invention.

In some embodiments, the conductive planar layer is formed by applying a nanoscale metal material and then sintering the nanoscale metal material. The sintered conductive planar layer formed has reflective properties and can be used as a reflective electrode in an array substrate.

In the present application, the term “nanoscale metal material” means that the size of the metal material is less than or equal to 1 nm to less than or equal to 200 nm, and is mainly comprised of a metal. The expression “mainly comprised of a metal” herein means that more than 80% of its ingredients is a metal element, preferably 90%, even 95% or more is a metal element. Of course, the size of the material may also be 1-100 nm, 5-80 nm, 5-50 nm, 5-40 nm, 10-35 nm, 10-30 nm, for example, 10 to 25 nm. The size of the material described herein refers to the size of a smaller extent of the metal material. For instance, if the metal material is microscopically fibrous, then the size is the diameter of the fiber, and if the metal material is microscopically spherical, then the size is the diameter of the sphere. In the present application, when the size of a nanoscale metal material is mentioned, it refers to the average value of the size of the metal material. In general, a nanoscale metal material may have various morphologies, e.g., spherical, fibrous, dendritic, flake and the like, and combinations thereof. When the size of a metal material is of nanoscale, the nanoscale metal material may be sintered at a temperature (e.g., a temperature of 130 for 400° C.) which is much lower than the melting temperature of a bulk metal material of the same kind.

In some embodiments, the nanoscale metal material as a nanoscale metal wire, a metal nano-particle, or a combination thereof. In some embodiments, the nanoscale metal material comprises a nanoscale silver material. These metal nanoscale materials can be commercially available, for example, for example, they can be conductive silver nano-solutions from South Korea Inktec Company. In some embodiments, the nanoscale silver material has a size of from 100 nm to 200 nm and can be sintered at a temperature of 390 to 400° C. or greater. In some embodiments, the nanoscale silver material has a size of from 50 nm to 130 nm and can be sintered at a temperature of 380 to 390° C. or greater. In some embodiments, the nanoscale silver material has a size of from 10 nm to 35 nm and can be sintered at a temperature of 130 to 140° C. or greater. When the nanoscale silver material has a size of smaller than 10 nm, it can be sintered at a lower temperature. Sintering at a relatively lower temperature can reduce the impact on the performance of the array substrate during the sintering process as much as possible.

In some embodiments, the conductive planar layers in different sub-pixel regions are separated and insulated from each other. The planar layers according to embodiments of the present invention are conductive and they are usually electrically connected to the pixel electrodes and switching elements of the sub-pixels. Therefore, the planar layers between various sub-pixels need to be separated and insulated from each other. There is no limitation to the method of separating and insulating them, and they can be separated and insulated using a pixel isolation layer. Alternatively, the insulating effect can also be produced by the gap in space.

In some embodiments, the conductive planar layer has a thickness of greater than 10 nm. In the present application, when “the thickness of the conductive planar layer” is mentioned, it refers to the thickness additionally increased except for leveling off the steps of the switching element. There is no particular limitation to the thickness of the conductive planar layer. However, when the conductive planar layer has a thickness of greater than 10 nm, particularly greater than 30 nm, the conductive planar layer can serve the function of being used as a reflective electrode well to avoid the transmission of light. In some embodiments, the conductive planar layer has a thickness of less than 4 μm, less than 3 μm, less than 2 μm, less than 1 μm, less than 100 nm, or less than 50 nm. The limitation of the thickness of the conductive planar layer to less than a certain value is for saving materials, saving the time of the production process, and reducing the thickness of the array substrate.

In some embodiments, the conductive planar layers in different sub-pixel regions are separated and insulated from each other. In some embodiments, the conductive planar layers in different sub-pixel regions are separated and insulated from each other by a pixel isolation layer. In the case of separating the conductive planar layers from each other with a pixel isolation layer, the pixel isolation layer can also be used for separating and insulating pixel electrodes from each other. This depends upon the height of the pixel isolation layer, and under the circumstance that the pixel isolation layer is only used to separate and insulate conductive planar layers from each other, the pixel isolation layer is generally allowed to have a height to be achieved by the conductive planar layers, or a greater height.

In some embodiments, the pixel electrodes in different sub-pixel regions are separated and insulated from each other by another pixel isolation layer. In some embodiments, the another pixel isolation layer may be formed on the pixel isolation layer used for isolating conductive planar layers. This is because in the same sub-pixel region, the pixel electrode and its corresponding conductive planar layer may have the same shape and area, and are mutually superimposed.

In some embodiments, the pixel electrode is electrically connected to the switching element via the conductive planar layer. In this case, the conductive planar layer is used as a reflective electrode, and is used for connecting the output electrode and the pixel electrode of the switching element. Under the circumstance that the switching element is a thin film transistor, the output electrode generally refers to the drain electrode of the thin film transistor.

In some embodiments, an inorganic buffer layer is disposed between the switching element and the planar layer. Because the conductive planar layer may affect the electrical properties of the switching element, an inorganic buffer layer can be first formed on the switching element prior to forming the conductive planar layer of the present invention. In this case, the inorganic buffer layer needs to be etched to expose the output electrode of the switching element. In some embodiments, in the process of forming a conductive planar layer, the conductive planar layer may contact the output electrode.

In some embodiments, the material of the inorganic buffer layer may be at least one selected from the group consisting of silicon oxide, silicon nitride and silicon oxynitride. Compared with an organic resin material, the stress between such inorganic materials and conductive planer layers is small, and therefore the electrode material may not tend to fall off. Meanwhile, the inorganic buffer layer may serve to protect the switching element, and to insulate the switching element (other than the output electrode) and the conductive layer planar.

In some embodiments, the inorganic buffer layer has a thickness of from 50 nm to 5000 nm, preferably 50 to 1500 nm, more preferably 50 to 500 nm. A too small thickness cannot achieve good protection and insulation effects, while a too large thickness may excessively increase the thickness of the array substrate and is not conducive to saving materials.

In some embodiments, the switching element is a thin film transistor.

In some embodiments, the array substrate further comprises an organic light-emitting layer above the pixel electrode and a transparent electrode above the organic light-emitting layer. In the present application, there is no limitation to the materials for the preparation of a transparent electrode. In some embodiments, the transparent electrode may be manufactured using an ITO electrode material, a carbon nanotube, a carbon nanowire or the like. Carbon nanotubes and nanowires are particularly excellent in terms of mechanical strength and electrical conductivity and are also light transmissive, and therefore can be used as the transparent electrode materials in the array substrate of the present invention. In some embodiments, the pixel electrode is an anode and the transparent electrode above the organic light-emitting layer is a cathode. In some embodiments, the pixel electrode is also a transparent electrode.

The array substrate according to embodiments of the present invention is particularly suitable for the preparation of an OLED device of a top emission type. Alternatively, the array substrate according to embodiments of the present invention is a top emission type. This is because a conductive planar layer having reflective properties is formed on the switching element, which will reflect the light produced in the light-emitting layer towards the top.

Another aspect of the present invention provides a display device comprising any array described above. Since the display device of the present invention comprises an array substrate having a conductive planar layer of the present invention, it has the advantages brought about by the array substrate.

Another aspect of the present invention further provides a method of manufacturing an array substrate, wherein the array substrate comprises: a substrate having a plurality of sub-pixel regions, wherein the array substrate in each sub-pixel region comprises: a switching element disposed on the substrate, a conductive planar layer disposed on the switching element, and a pixel electrode disposed on the planar layer, wherein the pixel electrode is electrically connected to the output electrode of the switching element. The method comprises: forming a switching element on each sub-pixel region of the substrate, forming a conductive planar layer on the switching element, and forming a pixel electrode on the conductive planar layer.

In the method of manufacturing an array substrate according to embodiments of the present invention, there is no limitation to the specific method of “forming a switching element on each sub-pixel region of the substrate” or to the type of the switching element.

FIG. 4-7 are schematic views of a method of preparing a switching element (a thin film transistor of a bottom gate type).

For example, a non-limiting method of preparing a switching element is as follows.

Firstly, depositing a layer of metal, typically molybdenum or copper, on a substrate (100), and forming a bottom gate structure, i.e., a gate electrode (101) (as illustrated in FIG. 4) comprising two identical gate electrode metal layers after etching.

Secondly, applying a layer of insulating material on the gate electrode (101) to form a gate insulator (GI) layer (102) (as illustrated in FIG. 5).

Thirdly, applying a semiconductor layer material, e.g., indium gallium zinc oxide (IGZO), on the gate insulation layer (102) to form an IGZO layer, i.e., a semiconductor layer (103), and depositing an inorganic non-metal material on the semiconductor layer (103) to form an etching barrier layer (104) after etching; the etching barrier layer is used for preventing damage to the semiconductor layer (103) during subsequent etching of the source electrode metal layer and the drain electrode metal layer (as illustrated in FIG. 6).

Fourthly, depositing a layer of metal on the etching barrier layer (104) to respectively form a source electrode (106), a drain electrode (105), and an intermediate metal layer (107) after etching (as illustrated in FIG. 7).

The switching element formed is as illustrated in FIG. 7. FIG. 7 illustrates the gate electrode (101), the gate insulator (GI) layer (102), the semiconductor layer (103), the etching barrier layer (104), the source electrode (106), the drain electrode (105) and the intermediate metal layer (107) on the substrate (100).

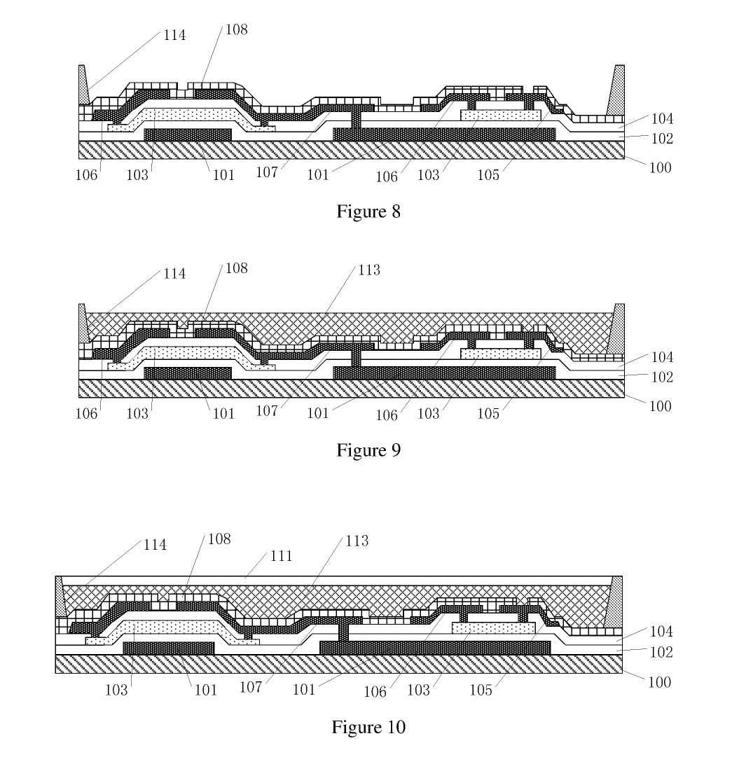

In some embodiments, the method for preparation of a switching element of a bottom gate type further comprises: depositing an inorganic buffer layer on the source electrode metal layer, the drain electrode metal layer and the intermediate metal layer, to form an inorganic buffer layer (108) (as illustrated in FIG. 8). In some embodiments, the inorganic buffer layer (108) is formed by chemical vapor deposition of silicon nitride, silicon oxide or silicon nitride oxide on the source electrode metal layer, the drain electrode metal layer and the intermediate metal layer. The switching element described in the present application may further comprise an inorganic buffer layer (108).

In the method of manufacturing an array substrate according to embodiments of the present invention, there is no limitation to the specific method which carries out the step of “forming a conductive planar layer on the switching element”.

In some embodiments, the step of forming a conductive planar layer on a switching element comprises: applying a nanoscale metal material onto the switching element, followed by sintering to obtain the conductive planar layer.

In some embodiments, the nanoscale metal material is applied by means of ink-jet printing and said sintering is performed at a temperature of 130-600° C. In some embodiments, the nanoscale metal material is used in the form of a solution of a metal nanoscale material, for example, the conductive silver nano-solution (in which the nanoscale silver particle size is about 25 nm) from South Korea Inktec Company may be used.

In some embodiments, prior to forming the conductive planar layer, an inorganic buffer layer is formed on the switching element, and then is etched to expose the output electrode of the switching element.

In some embodiments, prior to forming the conductive planar layer, a pixel isolation layer is formed, which defines the conductive planar layers on various switching elements. After forming the pixel isolation layer, a conductive planar layer may be formed by the method described above. The pixel isolation layer can also define the pixel electrodes on various switching elements, in which case, a pixel electrode can be formed directly after forming the conductive planar layer.

Under the circumstance that the pixel isolation layer fails to define the pixel electrodes on various switching elements, another pixel isolation layer used for separating and insulating pixel electrodes can be formed, to further form a pixel electrode.

In the method of manufacturing an array substrate of the present invention, there is no limitation to the specific method which carries out the step of “forming a pixel electrode on the conductive planar layer”.

In some embodiments, an ITO pixel electrode is deposited on the conductive planar layer by a sputtering method.

In some embodiments, after forming a pixel electrode, a pixel defining layer is formed on the pixel electrode, thereby defining the opening ratio of the array substrate.

### EMBODIMENTS

All the materials used in the embodiments of the present application are conventional, are commercially available from the market, or can be prepared by conventional methods.

### Comparative Example 1

FIG. 1 illustrates an example of an array substrate of a top emission type of the prior art, in which the array substrate of a top emission type comprises: a substrate 100, a gate electrode 101 on the substrate, a gate insulation layer 102, a semiconductor layer 103, an etching barrier layer 104, a source electrode 106, a drain electrode 105, an intermediate metal layer 107, an inorganic buffer layer 108, an organic resin planar layer 109, a reflective electrode 110, a transparent pixel electrode 111, and a pixel defining layer 112.

No pixel isolation layer is formed between the organic resin planar layers in this example. This is because the organic resin planar layers are non-conductive and all pixels share a large planar layer, which will not render electrical connection among the pixel electrodes.

### Embodiment 1

FIG. 2 illustrates an array substrate of a top emission type according to an embodiment of the present invention, comprising: a substrate 100 having a plurality of sub-pixel regions (FIG. 2 merely exemplifies one sub-pixel region), wherein the array substrate in each sub-pixel region comprises: a switching element 1 disposed on the substrate, a conductive planar layer 113 disposed on the switching element 1, and a pixel electrode 111 disposed on the planar layer, the pixel electrode 111 being electrically connected to the output electrode 105 (i.e., the drain electrode 105) of the switching element 1.

In the embodiment as illustrated in FIG. 2, the switching element 1 includes a gate electrode 101 on the substrate, a gate insulation layer 102, a semiconductor layer 103, an etching barrier layer 104, a source electrode 106, a drain electrode 105, and an intermediate metal layer 107. As can be seen from the figure, the switching element 1 as illustrated in FIG. 2 is a bottom gate type, which comprises two gate electrodes 101 on the substrate and a gate insulation layer 102 disposed thereon. Two semiconductor layers 103 are provided on the gate insulation layer 102, and are respectively above the two gate electrodes 101. An etching barrier layer 104 is provided above the semiconductor layer 103. A source electrode 106, a drain electrode 105, and an intermediate metal layer 107 are formed above the etching barrier layer 104, wherein the source electrode 106 on the left contacts the semiconductor layer 103 on the left via a through hole, and the source electrode 106 on the right contacts the semiconductor layer 103 on the right via a through hole, the intermediate metal layer 107 contacts the semiconductor layer 103 on the left via a through hole and contacts the gate electrode 101 on the right via another through hole, and the drain electrode 105 contacts the semiconductor layer on the right via a through hole. An inorganic buffer layer 108 is formed above the source electrode 106, the drain electrode 105, and the intermediate metal layer 107. The thickness on the entire plane of the inorganic buffer layer 108 varies slightly, and the steps formed on the switching element 1 are not planarized. A conductive planar layer 113 is provided above the inorganic buffer layer 108, planarizes the steps formed on the switching element 1 and can further serve as a reflective electrode. A pixel electrode 111 is formed on the conductive planar layer, and is electrically connected to the drain electrode 105 via a through hole across the conductive planar layer 113 and the inorganic buffer layer 108. The conductive planar layer 113 is made by sintering a nanoscale silver material. The pixel electrode 111 is formed by ITO that is deposited.

In the present embodiment, the conductive planar layer 113 has the function of reflecting light and is used as a reflective electrode. A through hole is formed in the conductive planar layer 113, and the pixel electrode 111 is directly electrically connected to the drain electrode via the through hole.

A pixel isolation layer 114 is formed between the conductive planar layers 113 in the adjacent sub-pixel regions of the present embodiment. The pixel isolation layer 114 is an insulator and is comprised of an organic or inorganic insulating material. The pixel isolation layer 114 separates and insulates all conductive planar layers from one another.

### Embodiment 2

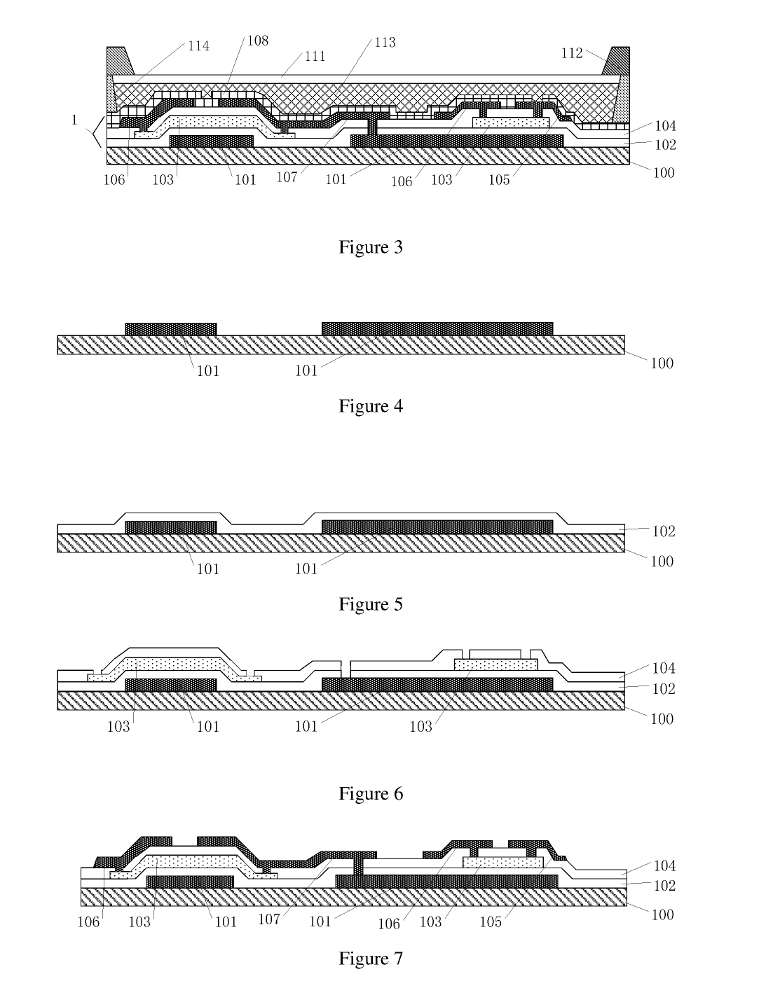

FIG. 3 illustrates an array substrate of a top emission type according to another embodiment of the present invention, in which the array substrate of a top emission type comprises: a substrate 100, a gate electrode 101 on the substrate, a gate insulation layer 102, a semiconductor layer 103, an etching barrier layer 104, a source electrode 106, a drain electrode 105, an intermediate metal layer 107, an inorganic buffer layer 108, a conductive planar layer 113, a reflective electrode 110, a transparent pixel electrode 111, a pixel isolation layer 114 and a pixel defining layer 112. In the present embodiment, the conductive planar layer 113 has the function of reflecting light and is used as a reflective electrode. The conductive planar layer 113 is electrically connected to the drain electrode 105 and the pixel electrode 111 is electrically connected to the drain electrode 105 via the conductive planar layer 113.

A pixel isolation layer 112 is formed between the conductive planar layers 113 in the present embodiment. The pixel isolation layer is an insulator and is comprised of an organic or inorganic insulating material. The pixel isolation layer separates and insulates all conductive planar layers from one another.

In the present embodiment, the part indicated by the reference sign 1 can be called a switching element, which includes a substrate 100, a gate electrode 101 on the substrate, a gate insulation layer 102, a semiconductor layer 103, an etching barrier layer 104, a source electrode 106, a drain electrode 105, and an intermediate metal layer 107.

### Embodiment 3

### Preparation of the Array Substrate of the Present Invention where a Buffer Layer is Formed

In the present embodiment, alkali-free glass is used as a substrate to form a switching element thereon required for TFT. As illustrated in FIG. 4, a gate metal material (Cu) is deposited and etched to form a bottom gate structure, i.e., a gate electrode (101), of a gate metal layer. Subsequently, as illustrated in FIG. 5, an inorganic insulating passivation layer having a film thickness of about 3 μm is formed. As illustrated in FIG. 6, the inorganic semiconductor material indium gallium zinc oxide is deposited and patterned, followed by depositing the etching protection layer 104, to form a through hole. As illustrated in FIG. 7, a source electrode 106 (which is connected to the semiconductor layer 103 via a through hole as illustrated in the figures), a drain electrode 105 (which is connected to the semiconductor layer 103 via a through hole as illustrated in the figures) and an intermediate metal layer 107 (which is connected to the gate electrode 101 via a through hole as illustrated in the figures) are formed to form a TFT switching element.

As illustrated in FIG. 8, an inorganic buffer (SiO₂) layer 108 is deposited and a pixel isolation layer 114 is formed. The drain electrode 105 is exposed after dry etching.

FIG. 9 illustrates that the metal ink-jet printing nano-material (the conductive silver nano-solution from South Korea Inktec Company, wherein the nanoscale silver particle size is about 25 nm) is formed into an non-sintered film layer having a thickness of 250 nm (which thickness can be 250 nm to 3 μm) after being ink-jet printed and injected onto the defined inorganic buffer layer 108, and sintered at a temperature of 250° C. (the sintering temperature can be 120 to 600° C., for example, 130 to 560° C.), to obtain a conductive planar layer 113 (which can be used as a reflective electrode) having a thickness of 200 nm. The conductive planar layer 113 is directly electrically connected to the drain electrode 105.

As illustrated in FIG. 10, the ITO layer is further deposited on the conductive planar layer 113 by sputtering to form a transparent ITO pixel electrode 111. The pixel electrode 111 is electrically connected to the drain electrode 105 via the planar conductive layer 113.

A pixel defining layer 112 is further formed on the pixel electrode 111, thereby forming the array substrate set forth in Embodiment 2.

In a further step, a positive photoresist (JEM-542, available from JSR Corporation) is coated by a spin coating process on a pixel electrode, and exposure and development are performed, to form a pixel defining layer 112 which defines the opening portion of the pixel electrode.

Further, by means of masking (e.g., by means of thermal evaporation deposition) or ink-jet printing, an OLED light-emitting material is sequentially deposited and formed on the defined pixel electrode, and finally an inorganic conductive oxide material ITO (IZO can also be used) is deposited as a transparent cathode (which has a micro-cavity structure).

Finally, an inorganic barrier layer of 2 μm is deposited by a method of chemical vapor deposition, to form the OLED light-emitting part.

The OLED light-emitting part can be further formed into a display device.

### Comparative Example 2

### Preparation of the Array Substrate of Comparative Example 1

In this example, alkali-free glass is used as a substrate to form a switching element thereon required for TFT. The TFT switching element formed is the same as that in Embodiment 3.

After forming the TFT switching element, a wet film of acrylic monomers is formed on the switching element by spin coating, a pre-cured film is formed by heating and pre-curing, and the pre-cured film is formed into a planar layer 109 of acrylic resins (FIG. 1) having a thickness of 1500 nm in the part other than the through hole by means of masking and exposing. The through hole is etched on the planar layer 109 to expose the drain electrode 105.

The metal Ag that is 200 nm thick is deposited on the planar layer 109 as a reflective electrode 110, and the ITO layer is deposited to form a transparent ITO pixel electrode 111. The reflective electrode 110 is in direct contact with the drain electrode 105. The pixel electrode 111 is electrically connected to the drain electrode 105 via the reflective electrode 110.

Accordingly, the array substrate described in Comparative Example 1 is formed.

### Test 1

The stability of the array substrate is tested, and it is found that the stability is improved.

Evaluation is made by the checkerboard grid method according to JIS K 5400. The specific method is as follows: the array substrate prepared by Embodiment 3 (which corresponds to the array substrate of Embodiment 2) and Comparative Example 2 (which corresponds to the array substrate of Comparative Example 1) is carved into a chestboard grid with a cutter to form 25 grids at an interval of 2 mm. A 3M 600 transparent glass paper adhesive tape is pasted, and then one end of the 3M adhesive tape is held at an angle of 60 degrees for smooth peeling within 0.5-1 seconds. The 3M adhesive tape which has been tested is pasted on a test board for reference and determination. The adhesion state of the coating film will be visually observed after peeling the adhesive tape, where evaluation is made on the basis of the grid with no peel-off as OO, the grid with less than or equal to ⅕ of peel-off as O, and the grid with greater than ⅕ of peel-off as x. The results are illustrated as follows:

TABLE 1

| | Evaluation | Adhesive | Evaluation |
|---|---|---|---|
| | method | tape used | result |
| Embodiment 3 | JIS K 5400 | Type 600 | OO |
| (the array | | transparent glass | |
| substrate of | | paper adhesive | |
| Embodiment 2) | | tape from | |
| | | 3M Company | |
| Comparative | JIS K 5400 | Type 600 | O |
| Example 2 | | transparent glass | |
| (the array substrate | | paper adhesive | |
| of Comparative | | tape from 3M | |
| Example 1) | | Company | |

The foregoing is merely exemplary embodiments of the invention, but is not used to limit the protection scope of the invention. The protection scope of the invention shall be defined by the attached claims.

The present application claims the priority of the Chinese patent application No. 201510453722.7 submitted on Jul. 29, 2015, and the content disclosed in the above Chinese patent application is incorporated herein by reference as part of the present application.

1. An array substrate, comprising:
a substrate having a plurality of sub-pixel regions,
wherein the array substrate in each sub-pixel region comprises: a switching element disposed on the substrate, a conductive planar layer disposed on the switching element, and a pixel electrode disposed on the planar layer, the pixel electrode being electrically connected to an output electrode of the switching element.

2. The array substrate according to claim 1, wherein the conductive planar layer is a metal-containing conductive planar layer.

3. The array substrate according to claim 1, wherein the conductive planar layer is formed by sintering a nanoscale metal material.

4. The array substrate according to claim 3, wherein the nanoscale metal material is a metal nano-wire, a metal nano-particle, or a combination thereof.

5. The array substrate according to claim 1, further comprising a pixel isolation layer which separates and insulates the conductive planar layers in different sub-pixel regions from each other.

6. The array substrate according to claim 1, wherein the conductive planar layer has a thickness of equal to or greater than 10 nm to less than 1 μm.

7. The array substrate according to claim 1, wherein the pixel electrode is electrically connected to the output electrode of the switching element via the conductive planar layer.

8. The array substrate according to claim 1, wherein an inorganic buffer layer is disposed between the switching element and the conductive planar layer.

9. The array substrate according to claim 4, wherein the nanoscale metal material comprises a nanoscale silver material.

10. The array substrate according to claim 8, wherein the inorganic buffer layer has a thickness of from 50 nm to 1500 nm.

11. The array substrate according to claim 1, wherein the switching element is a thin film transistor and the output electrode of the switching element is a drain electrode of the thin film transistor.

12. The array substrate according to claim 1, wherein the array substrate further comprises an organic light-emitting layer above the pixel electrode and a transparent electrode above the organic light-emitting layer.

13. The array substrate according to claim 1, wherein the conductive planar layer and the pixel electrode are in direct contact with each other.

14. The array substrate according to claim 1, wherein a material of the pixel electrode comprises at least one selected from the group consisting of transparent conductive oxides, carbon nanotubes and carbon nanowires.

15. A display device comprising the array substrate according to claim 1.

16. A method of manufacturing an array substrate comprising a substrate having a plurality of sub-pixel regions, wherein the method comprises:
forming a switching element on each sub-pixel region of the substrate,
forming a conductive planar layer on the switching element, and
forming a pixel electrode on the conductive planar layer, wherein the pixel electrode is electrically connected to an output electrode of the switching element.

17. The method according to claim 16, wherein forming the conductive planar layer on the switching element comprises: applying a nanoscale metal material onto the switching element, and then sintering the nanoscale metal material to obtain the conductive planar layer.

18. The method according to claim 16, which, prior to forming the conductive planar layer, further comprises forming an inorganic buffer layer on the switching element and etching the inorganic buffer layer to expose the output electrode of the switching element.

19. The method according to claim 16, which, prior to forming the conductive planar layer, further comprises forming a pixel isolation layer that separates the conductive planar layers in different sub-pixel regions from each other.

20. (canceled)

21. The method according to claim 17, wherein the nanoscale metal material is applied by ink-jet printing, screen printing, or transfer printing, and the sintering is performed at a temperature of from 120 to 600° C.

22-23. (canceled)
